(19) United States
(12) Patent Application Publication
(10) Pub. No.: US 2013/0075840 A1
(43) Pub. Date: Mar. 28, 2013

(54) METHOD FOR FABRICATION OF A MAGNETIC RANDOM ACCESS MEMORY (MRAM) USING A HIGH SELECTIVITY HARD MASK

(71) Applicants: Kimihiro Satoh, Beaverton, OR (US); Jing Zhang, Los Altos, CA (US); Yiming Huai, Pleasanton, CA (US)

(72) Inventors: Kimihiro Satoh, Beaverton, OR (US); Jing Zhang, Los Altos, CA (US); Yiming Huai, Pleasanton, CA (US)

(73) Assignee: AVALANCHE TECHNOLOGY, INC., Fremont, CA (US)

(21) Appl. No.: 13/369,756

(22) Filed: Feb. 9, 2012

Related U.S. Application Data
(60) Provisional application No. 61/441,228, filed on Feb. 9, 2011.

(51) Int. Cl. H01L 45/00

(52) U.S. Cl. CPC H01L 45/04
USPC 257/421

(57) ABSTRACT

A self-aligned via of a MRAM cell that connects a memory element including a top electrode, a memory element stack having a plurality of layers, and a bottom electrode to a bit line running over array of the memory elements. The self-aligned via also serves as a hard mask for memory element etching. The hard mask material has high selectivity in the etching ambient to maintain enough remaining thickness. It is also selectively removed during dual damascene process to form a self-aligned via hole. In one embodiment, Aluminum oxide or Magnesium oxide is adapted as the hard mask.

### CROSS-REFERENCE TO RELATED APPLICATIONS

This application claims priority to U.S. Provisional Application No. 61/441,228, filed on Feb. 9, 2011, by Kimihiro Satoh, et al., and entitled “A Method For Fabrication of a Magnetic Random Access Memory (MRAM) Using a High Selectivity Hard Mask.

### BACKGROUND OF THE INVENTION

1. Field of the Invention

The present invention relates to the fabrication of a Magnetic Random Access Memory (MRAM) magneto tunnel junction (MTJ), and, more particularly, to improve yield and the reliability of such manufacturing.

2. Description of the Prior Art

STTMRAM (Spin Torque Transfer Magnetic random access memory) is the next generation of non-volatile memory currently under development. A memory element of MRAM including a magneto tunnel junction (MTJ) in-between a top and a bottom electrode is the essential ‘memory’ part of the MRAM. Fabrication of the memory element involves forming a hard mask on top of the memory element stack layer, imaging mask pattern in photoresist coated on the top of hard mask, transferring the photoresist image to the hard mask and further to the memory element. However, prior art techniques which work well on prior technology yield undesirable effects during such a process in advanced recent technology node. The hard mask is typically etched at a rate that is too high to allow the hard mask to remain before etching is completed. Stated differently, the etch rate of hard mask is higher than the etch rate of the target.

In today's processes, silicon nitride, silicon oxide or derivatives are generally used as the hard mask and it is itself etched before the target, i.e. the memory element stack, is etched, resulting in complete removal of the hard mask. Absence of the hard mask undesirably exposes a top electrode at top of the memory element stack. Additionally, at times, the memory element undesirably starts to be eroded, resulting in dome-shaped top and slanted side wall profile. Such a hard mask is referred to herein as “low selectivity hard mask”.

FIG. 1 shows the effect of a low selectivity hard mask on the memory element stack, including an MTJ, during fabricating the memory element. In the prior art FIG. 1, an MTJ is shown formed on top of a bottom electrode and on top of the MTJ is shown formed a top electrode. On top of the top electrode is shown formed a prior art hard mask and on top of the hard mask is shown formed a photoresist layer. The structures to the right of the left-most structure are the resulting memory element. During etching, the prior art hard mask is reduced in thickness to the point where the top electrode is exposed, as shown by the structure to the right-most side of the page. This significantly reduces the process window of memory element fabrication.

A summary of the foregoing discussion in light of FIG. 1 is now presented. MRAM is fabricated by inserting a magnetic memory element process into conventional CMOS BEOL (Back End Of Line) process. Magnetic memory element process consists of MTJ stack layer deposition, patterning the memory element and inter-connection to upper metal layers. The memory element stack layer consists of bottom electrode, MTJ (Magnetic Tunnel Junction) and top electrode. The MTJ pattern is imaged in photo resist and transferred into the stack layer with anisotropic dry etching. Bottom and Top electrodes are typically made of tantalum (Ta) and MTJ is typically made of multilayer structures with ferromagnetic layers separated by non-magnetic spacing layer.

Silicon oxides, silicon nitrides and their derivatives are often used as hard mask for the magnetic memory element stack etching. Silicon oxides, silicon nitrides and their derivatives are well known materials in semiconductor fabrication processes and commonly employed. However they are not the best material for this purpose. Presuming an etching method using Chlorine based chemistry for the hard mask, methanol based chemistry for the MTJ and fluorocarbon/Oxygen based chemistry for top and bottom electrode are used, the initial hard mask thickness should be optimized based on etch rate and stack structure to keep hard mask remaining after the etching. However, thick hard mask is adverse for fine patterning and photo resist may become thicker. Etching bias is getting bigger with the thickness.

What is needed is a method and apparatus of manufacturing a reliable MRAM.

### SUMMARY OF THE INVENTION

An embodiment of the invention includes a self-aligned via of a MRAM cell that connects a memory element including a top electrode, a memory element stack having a plurality of layers, and a bottom electrode to a bit line running over array of the memory elements. The self-aligned via also serves as hard mask for memory element etching. The hard mask material has high selectivity in the etching ambient to maintain enough remaining thickness after etching process. It is also selectively removed during dual damascene process to form a self-aligned via hole. For example, Aluminum oxide and Magnesium oxide meet these requirements. Their etch rates with Carbon fluorides for the top and bottom electrode is extremely slow. Their selectivity with Methanol or Carbonyl/Ammonia for MTJ stack film is higher than 10. They can be dissolved in acid or alkali solution. Since ILD (inter layer dielectrics) is not dissolved in in the solutions, the hard mask is removed selectively to form the self-aligned via hole during dual damascene process.

Another embodiment of the invention serves to directly contact to a bit line using an electrically conductive material as a hard mask. The hard mask is used for directly connecting the memory cell and the bit line without via process. The hard mask material has high selectivity in the etching ambient to maintain enough remaining thickness after etching process. For example, etch rates of Cu or Al with Carbon fluorides for the top and bottom electrode is extremely slow. Their selectivity with Methanol or Carbonyl/Ammonia for MTJ stack film is increased with etching parameters such as lower bias.

### IN THE DRAWINGS

FIG. 1 shows the effect of a low selectivity hard mask on an MRAM, including an MTJ, during the manufacturing of the MRAM.

FIG. 2 shows the effect of using a high selectivity hard mask to manufacture the MRAM 10.

FIGS. 3-11 show, in relevant part, a method of manufacturing the MRAM 10, in accordance with a method of the present invention.

FIGS. 12-13 show, in relevant part and in combination with FIGS. 3-10, a method of manufacturing the MRAM 10, in accordance with another method of the present invention.

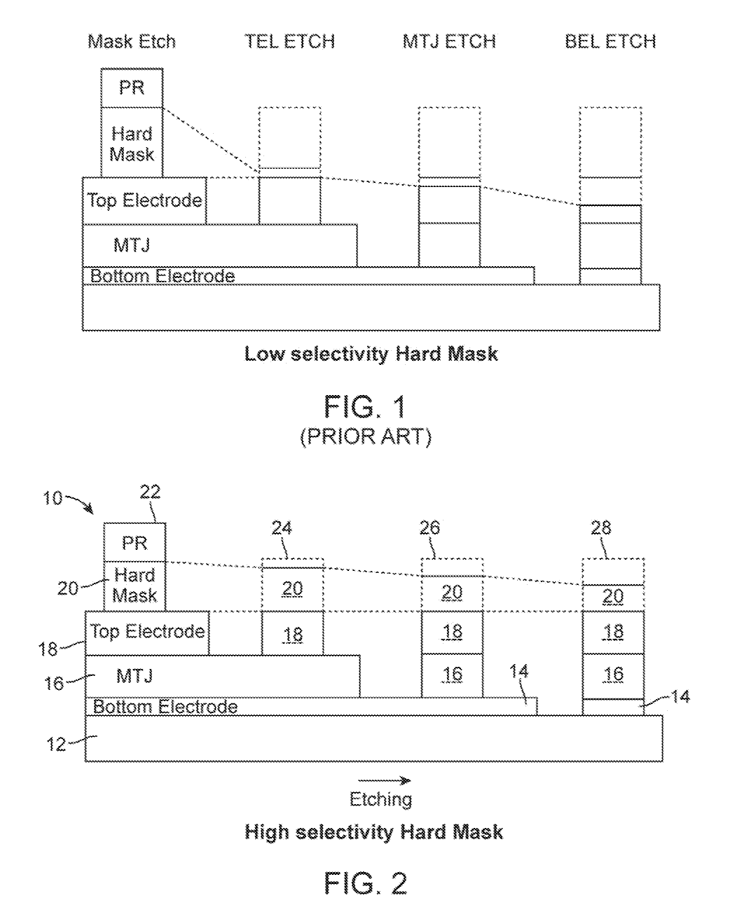

### DETAILED DESCRIPTION OF THE VARIOUS EMBODIMENTS

In the following description of the embodiments, reference is made to the accompanying drawings that form a part hereof, and in which is shown by way of illustration of the specific embodiments in which the invention may be practiced. It is to be understood that other embodiments may be utilized because structural changes may be made without departing from the scope of the present invention. It should be noted that the figures discussed herein are not drawn to scale and thicknesses of lines are not indicative of actual sizes.

FIG. 2 shows the effect of using a high selectivity hard mask to manufacture the MRAM 10. In FIG. 2, the MRAM 10 is shown as it undergoes etching. During such a process, MRAM 10 appears as 24, 26 and 28. MRAM 10 is shown to comprise a bottom electrode (BE), formed on top of the substrate 12. On top of the BE 14 is shown formed MTJ 16 and on top of the MTJ 16 is shown formed top electrode (TE) 18. On top of the TE 18 is shown formed hard mask 20 and on top of the hard mask 20 is shown formed photoresist 22. The hard mask is a high selectivity hard mask in that its etching rate is lower than that of the target, i.e. MTJ 16.

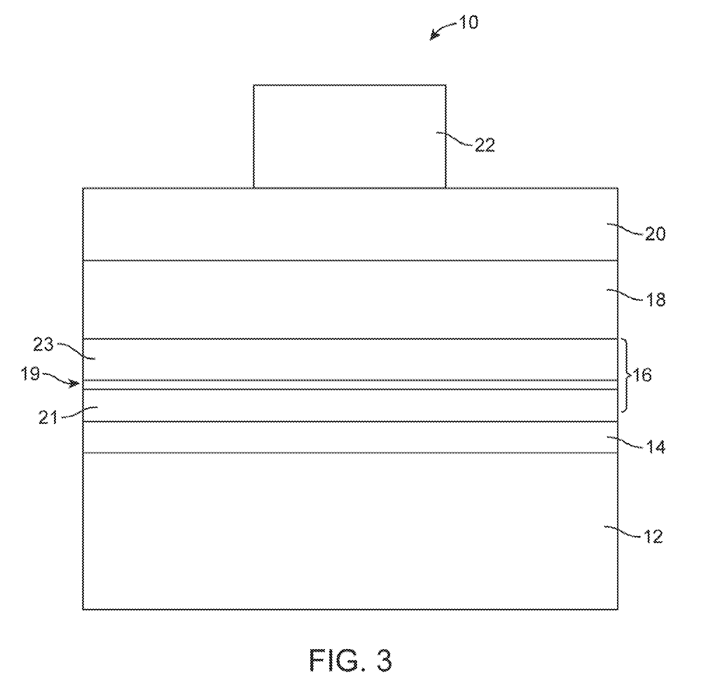

In some embodiments, the hard mask 20 is made of aluminum (Al), or copper (Cu), or its alloys, or aluminum oxide (AlO), or magnesium oxide (MgO). FIGS. 3-11 show, in relevant part, a method of manufacturing the MRAM 10, in accordance with a method of the present invention. In FIG. 3, the BE 14 is shown formed on top of the substrate 12, as in FIG. 2. The MTJ 16 is shown formed on top of the BE 14 and comprises a fixed layer 21, formed on top of the BE 14 and a tunnel layer 19, formed on top of the fixed layer 21 and a free layer 23, formed on top of the tunnel layer 19. The TE 18 is shown formed on the free layer 23 of the MTJ 16. The free layer 23 has a magnetization orientation that switches relative to the direction of magnetization of the layer 21 thereby storing a bit or state. This is the reason for the MRAM 10 operating as a memory element.

On top of the TE 18 is shown formed the hard mask 20 and on top of the hard mask 20 is shown formed the photoresist (PR) image 22 as in FIG. 3. The PR image 22 is subsequently transferred into hard mask 20, Top electrode 18, MTJ 16 and bottom electrode 14 with reactive ion etching (RIE) using appropriate etchant chemistry at each etching stage. The thickness of the hard mask 20 is designed with considering thickness budget as minimizing the remaining at the completion of entire the memory element etch.

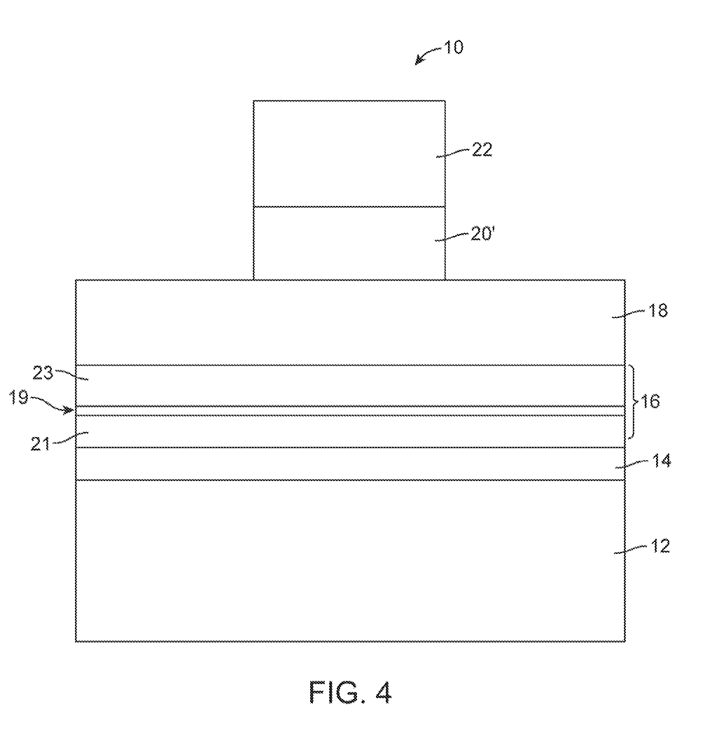

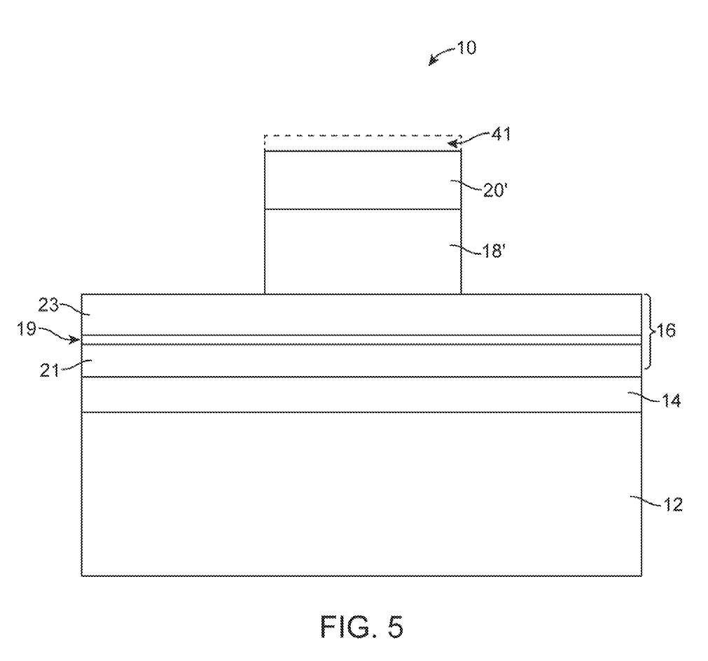

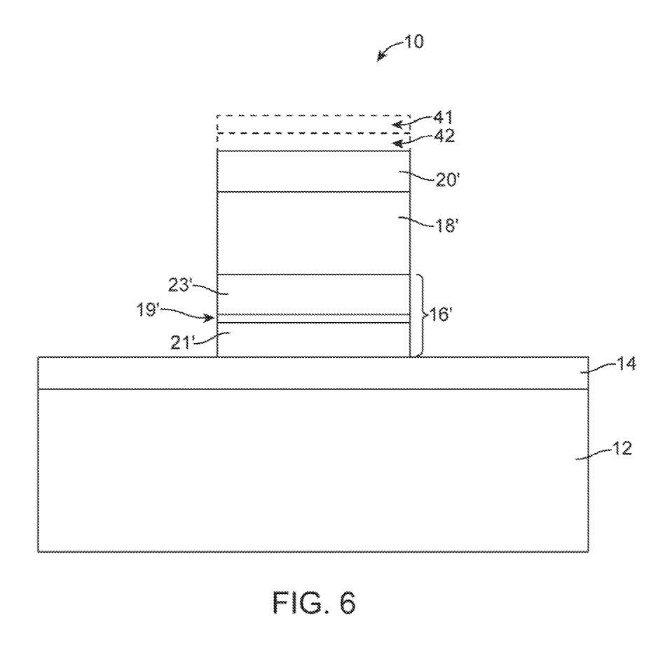

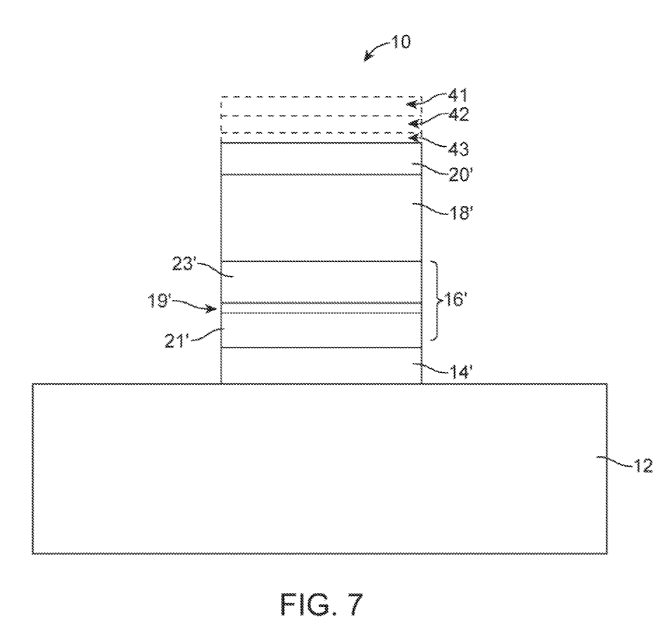

Next, during the fabrication, as shown in FIG. 4, The photoresist image 22 is transferred into the hard mask layer 20 to create hard mask image 20′ with anisotropic dry etching like as reactive ion etching (RIE). BCl₃/Cl₂ based chemistry as etchant is used. Passivation gas can be introduced to make up the sidewall of the hard mask for convenience of following process. In FIG. 5, the hard mask 20′ is transferred into the top electrode layer 18 to create the top electrode structure 18′. CF4/O2 based chemistry is used as etchant. The hard mask 20′ is lowered during the etching. The thickness of reduction of the hard mask 20′ during this step is shown by 41, in FIG. 5. The loss 41 is estimated by less than 10% of the TE 18 Next, as shown in FIG. 6, the MTJ 16 is etched forming MTJ 16′ to transfer the hard mask image into the layer, using known etching techniques, methanol based RIE (reactive ion etching). The thickness of the hard mask 20′ is reduced further only by the thickness of 42. In some embodiments, the thickness of 42 is 20% or less of the thickness of the MTJ 16′. Next, BE 14 is etched, as shown in FIG. 7, which results in the thickness of the hard mask 20′ being reduced by the thickness of 43. The total thickness of 41, 42 and 43 combined, which is the total thickness loss of the hard mask 20, is less than the thickness of the hard mask 20′ after the step of FIG. 6, thereby advantageously leaving a respectably size of the hard mask 20 left after all etching is completed whereas in prior art techniques, during such etching processes, the hard mask would have disappeared. In some embodiments, the thickness of 43 is one-tenth that of the thickness of BE 14. Moreover, the difference in thickness of the layers BE 14′, the MTJ 16′ and the TE 18′ is approximately 10% of the thickness of the layers BE 14, MTJ 16 and TE 18.

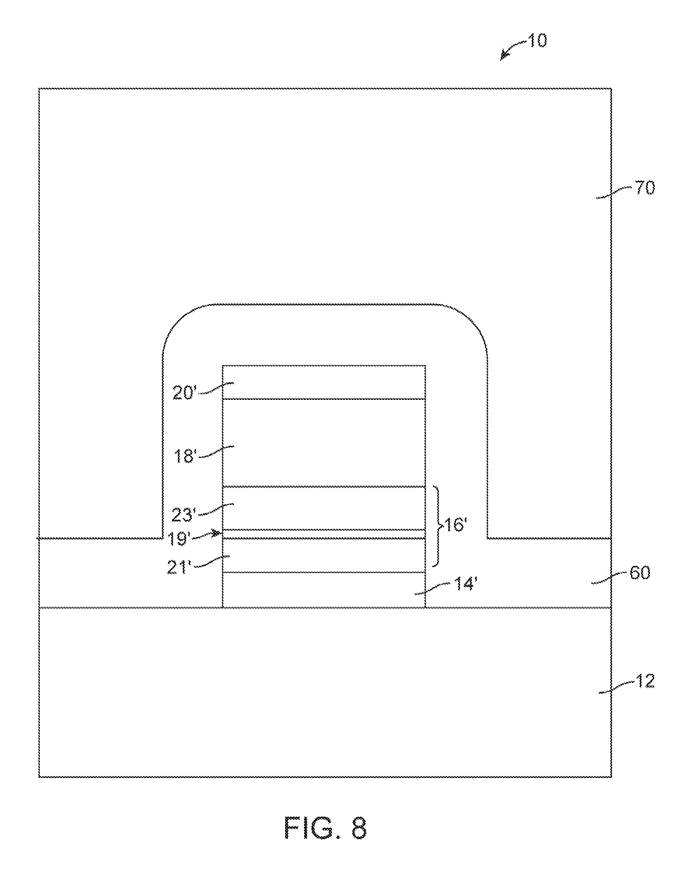

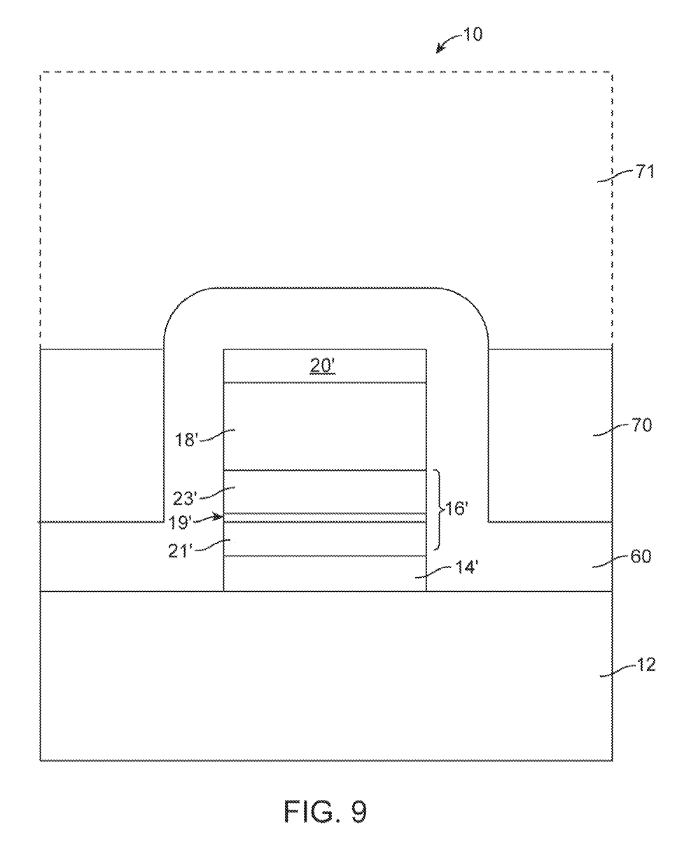

Next, in FIG. 7, a silicon nitride layer 60 is deposited on top of the hard mask 20′ to prevent the MTJ sidewall from oxidation and over all remaining layers of the MRAM 10 including the substrate 12. Next, a silicon oxide layer 70 is formed on top of the layer 60 and chemical mechanical polishing (CMP) is performed on all layers shown in FIG. 8. The reason for the formation of the layers 60 and 70 is because after CMP, further etching is performed to create a trench for copper to be filled into to form a wire. During the latter etching process, it is desirable to prevent etching of the layer 60 and because the etching rate for oxide and nitride are different, with nitride having a lower etching rate than oxide, the layer 60 is protected and maintained while the layer 70 is etched substantially above the hard mask 20′ and maintained on either side thereof, as shown in FIG. 9. That is, etching stops when the layer 60 is encountered thereby leaving the layer 70 at either side of the hard mask 20′. In FIGS. 9 and 10, 71 defines the areas of the layer 70 that are etched.

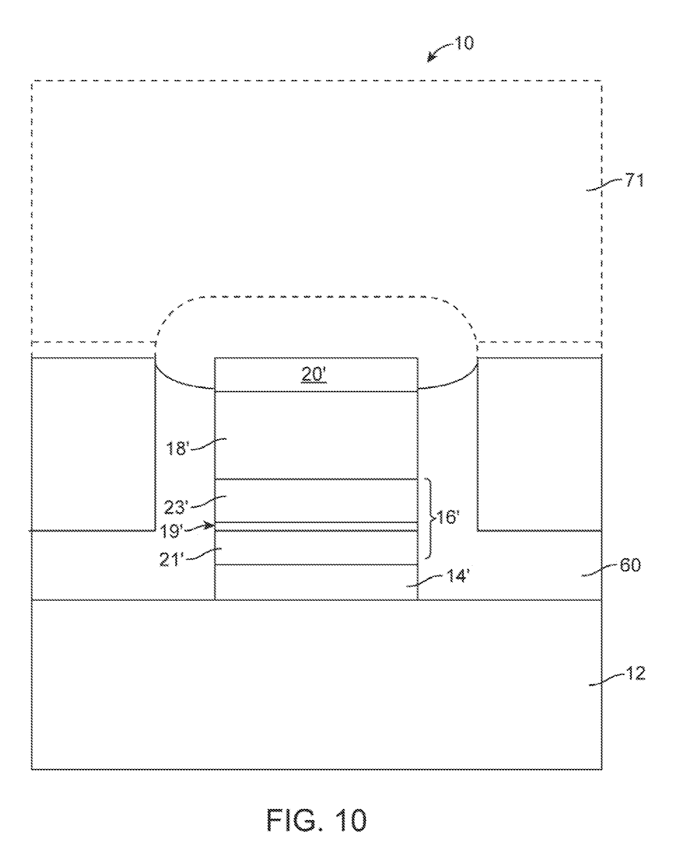

Next, selective removal of the layer 60 in areas that are between the layer 70 and the MRAM 10 (or hard mask 20′) is performed by etching using known techniques, such as oxygen rich CF4/02 process, which is known to etch nitride more than silicon oxide, leaving the structure shown in FIG. 10. In FIG. 10, trenches are shown formed with each trench adjacent to the side of the hard mask 20′ and the MRAM and the layer 70.

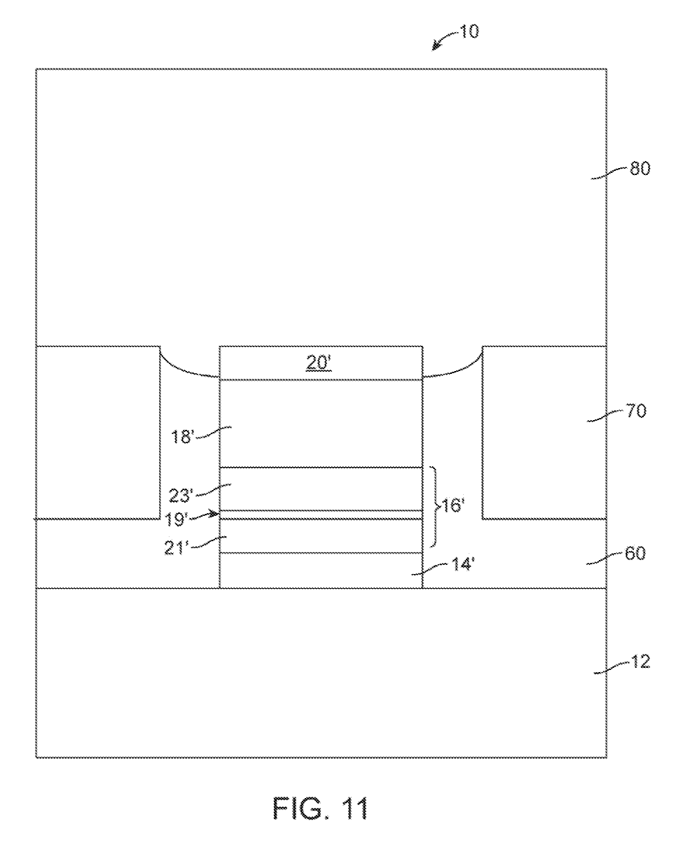

FIG. 11 shows the following step where the hard mask 20′ is made of aluminum. Copper 80 is deposited with electro-plating following seed layer deposition on the structure of FIG. 10 and allow CMP to remove excessive copper to form the copper wire in the trench.

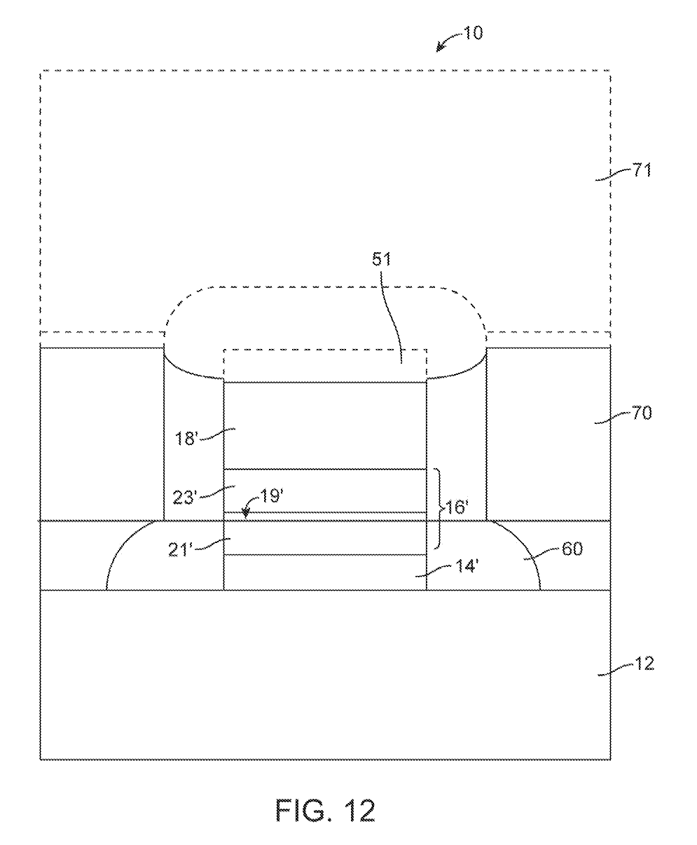

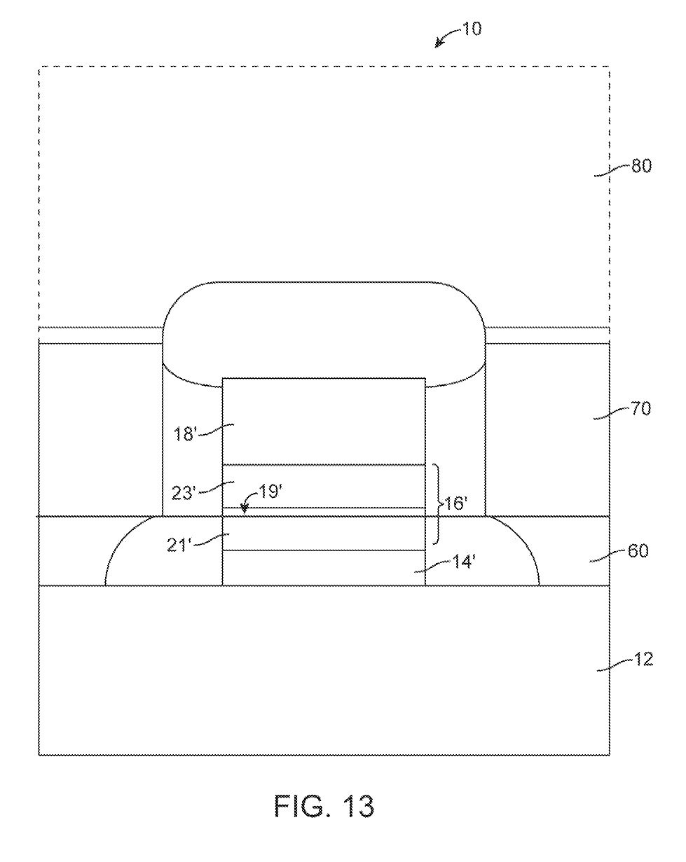

FIGS. 12-13 show, in relevant part and in combination with FIGS. 3-10, a method of manufacturing the MRAM 10, in accordance with another method of the present invention.

FIG. 12 continues from FIG. 10 in the case where aluminum oxide (AlO) makes up the material used as the hard mask 20. In FIG. 12, the hard mask is stripped by potassium hydride (KOH) wet etch or chlorine chemistry dry etch. This results in the gap 51 where the hard mask 20 used to occupy. The gap 51 is important in that it protects shorting between the MTJ and copper that is deposited in a later step. In FIG. 10, the hard mask 20′ was not stripped because it was made of aluminum, which is non-conducting.

Next, in FIG. 13, copper 80 is deposited and serves as the wire allowing for electrical connection the MRAM 10 to other circuits/structures, similar to that shown in FIG. 11. Copper is filled in the area designated by reference number 71 in FIG. 12, and CMP removes excess copper.

Although the present invention has been described in terms of specific embodiment, it is anticipated that alterations and modifications thereof will no doubt become apparent to those more skilled in the art. It is therefore intended that the following claims be interpreted as covering all such alterations and modification as fall within the true spirit and scope of the invention.

What is claimed is:

1. A magnetic random access memory (MRAM) cell comprising:
a MRAM element including,
a magneto tunnel junction (MTJ) formed on top of a substrate;
a top electrode formed on top of the MTJ; and
a self-aligned via also serving as an etching hard mask;
a metal line connected to said MRAM element with said self-aligned via serving as an etching hard mask.

2. The MRAM cell of claim 1 wherein said etching hard mask that is made of aluminum oxide.

3. The MRAM cell of claim 1 wherein said etching hard mask that is made of magnesium oxide.

4. A magnetic random access memory (MRAM) cell comprising:
a MRAM element including,
a magneto tunnel junction (MTJ) formed on top of a substrate;
a top electrode formed on top of the MTJ; and
an electrically conductive remaining etching hard mask;
a metal line connected to said MRAM element with said hard mask.

5. The MRAM cell of claim 4 wherein said electrically conductive etching hard mask is made of aluminum.

6. The MRAM cell of claim 4 wherein said etching hard mask is made of copper.
